(19) United States
(12) Patent Application Publication
(10) Pub. No.: US 2006/0278159 A1
(43) Pub. Date: Dec. 14, 2006

(54) Nanostructures

(76) Inventors: Duncan Hudson Gregory, Nottingham (GB); Alexander Georgina Redeliffe Gordon, Nottingham (GB)

Correspondence Address: LAWSON & WEITZEN, LLP, 88 BLACK FALCON AVE, SUITE 345, BOSTON, MA, 02210, US

(21) Appl. No.: 10/540,161

(22) PCT Filed: Dec. 18, 2003
(86) PCT No.: PCT/GB03/05565

§ 371 Date: Jun. 6, 2006

(30) Foreign Application Priority Data
Dec. 20, 2002 (GB) 0229662.2

(51) Int. Cl. C30B 7/00; C30B 21/02; C30B 28/06

(52) U.S. Cl. 117/68

(57) ABSTRACT

The present invention relates to nanotubes and in particular to a process and apparatus for the preparation of nanotubes. In particular, the present invention relates to nanotubes which are made from materials other than carbon or nanotubes containing carbon but which would not ordinarily be classed as carbon nanotubes on account of their low carbon content. The nanostructures of the present invention have a number of applications such as: ionic conductors/battery components, hydrogen storage, templating nanowires, electrical devices, catalysis and synthesis, flat screen technology, and mechanical applications.

The present invention relates to nanotubes and in particular to a process and apparatus for the preparation of nanotubes. More specifically, the present invention relates to nanotubes which are made from materials other than carbon or nanotubes containing carbon but which would not ordinarily be classed as carbon nanotubes on account of their low carbon content. More particularly, the invention also relates to precisely defined nanostructures such as tubes, rods and fibres and other nanostructures but not to isotropic structures such as nanoparticles (for example, spheres) which lack any coherent structure and which thus do not form part of the invention.

Carbon nanotubes are effectively cylindrical structures based on a hexagonal lattice of carbon atoms that forms crystalline graphite. Carbon nanotubes may have a single wall or a multi-walled structure. Carbon nanotubes can behave as a semiconductor or a metal depending on the diameter and arrangement of the graphitic rings in the walls.

Carbon nanotubes are thus unique nanostructures having unusual electronic and mechanical properties. Carbon nanotubes usually have a diameter in the order of 0.4 nanometres (nm) to 100 nm and a length of up to about 1 cm. Nanotubes can be considered as prototypes for one-dimensional quantum wire and these properties derive specifically from their structure. Groups of nanotubes can be joined together to form molecular wires. In effect, carbon nanotubes are a type of fullerene and the ends of carbon nanotubes must be formed from fullerene-like caps. This has the consequence that the diameter of a carbon nanotube can only be as small as a fullerene molecule.

The one-dimensional electronic properties of carbon nanotubes arise due to the quantum confinement of electrons in a direction normal to the nanotube axis. The result is that a number of one-dimensional conduction and valence bands are produced with most carbon nanotube structures being semiconducting and a small number being metallic in behaviour, depending on the diameter and arrangement of the hexagonal network of carbon atoms forming the nanotube.

There has been much anticipation regarding the potential interesting electrical, magnetic, non-linear-optical, thermal and mechanical properties of carbon nanotubes. Indeed, carbon nanotubes exhibit mechanical strength and strain characteristics which are greater than those of steel and other alloys. At the same time, carbon nanotubes have a low density which is similar to or less than ceramic or polymeric materials of conventional types.

WO02/081366 describes a process for producing carbon nanotubes in which a substrate capable of supporting carbon nanotube growth is provided in a reaction chamber in the proximity of a heating element. Gaseous carbonaceous material is then passed into the reaction chamber so that it passes over and contacts the substrate with the result that the carbon nanotubes grow on the substrate. This process is said to allow the preparation of carbon nanotubes at temperatures as low as 300° C.

WO02/42204 discloses a process for preparing carbon nanotube composite structures and this patent attempts to overcome the problems of producing carbon nanotube composites with denser material such as metals, ceramics or polymer matrices. It is suggested that one problem in the production of such material stems from the fact that the density differences between the materials results in a gravitational separation of the composite materials from the lightweight carbon nanotubes. In addition, the electrostatic properties lead to the agglomeration of the carbon nanotubes during composite formation with the result that a homogeneous matrix of composite material cannot reliably be formed.

There is no disclosure in the prior art of any previous work on lithium nitride nanotubes or related anisotropic (or indeed isotropic) nanostructures. Further there is no evidence of nanostructured nitrides, carbides or other compounds with non-metallic elements formed containing group 1 elements.

Magnesium nitride is the only example in the prior art of a nanostructured group 2 element material (CN1109022A). This previous technology describes nanoparticles (i.e. approx isotropic particles—spheres—of nm dimensions) and not an anisotropic structure as in the present invention.

WO98/24576A discloses “nanostructured” metals, alloys and carbides but these are again approx isotropic nanoparticles of <100 nm diameter.

U.S. Pat. No. 5,876,682 discloses nanostructured nitride ceramic powders of <1000 nm and again these are essentially isotropic materials.

CN1348919A discloses nanosized titanium carbide but again these are nanoparticles and this patent only discloses a single material. Similarly, CN1371863 discloses nanosized titanium boride and again the material is in the form of nanoparticles. This patent also only covers one example.

U.S. Pat. No. 5,997,832 discloses nanorods of metal carbides with diameters <100 nm and aspect ratios of 10-1000 and WO96/30570A discloses nanofibrils of carbides of any metal but in each case there is no disclosure of any nanotube type structure.

However, the prior art does not disclose any form of nanotube based either entirely or predominantly on material other than carbon or indeed any anisotropic nanostructures based on Group IA metals. The interest in carbon nanotubes arises because of the possibility of allowing step changes in the performance of a wide range of systems. However, the number of applications of carbon nanotubes is limited by the range of structures and electronic properties available. The present invention aims to provide a wide range of nanoscale structures such as nanorods, nanofibres and nanotubes from materials other than carbon. It is also within the scope of the invention to produce nanoscale structures which incorporate carbon but which would not be classified as carbon nanostructures because of their low (ie less than 50% carbon content).

According to one aspect of the present invention there is provided an isotropic nanoscale structure formed from at least one element selected from groups IA and IIA of the periodic table and at least one element selected from groups IIIA, IVA, and VA.

In an embodiment, the nanostructure is inorganic.

Preferably, the structure is formed from at least one element selected from group IA and of the periodic table and at least one element selected from groups IIIA, IVA, and VA. More preferably, the structure is formed from at least one element selected from group IA and at least one element selected from group VA.

Preferably, the element of group IA is lithium, sodium or potassium and, most preferably the element is lithium.

In an embodiment, the element selected from groups IIIA, IVA, and VA is a non-metallic element selected from those groups. Thus the element(s) selected from Groups IIIA, IVA, and VA is one or more of boron, carbon, silicon or nitrogen. Most preferably, the non-metallic element is a group VA element and, most preferably the element of group VA is nitrogen.

Thus, most preferably, the nanostructure is based on lithium nitride (Li₃N).

Preferably, the structure is a nanotube, nanorod or nanofibre. More preferably the structure is a nanotube.

In the nanostructures of the present invention, it is possible to replace some or all of the metallic element of group IA and IIA with another element such as hydrogen or a transition metal, preferably copper, nickel, cobalt, iron, manganese and zinc, in order to modify the properties of the nanostructure. Thus a transitional metal or hydrogen may also optionally be present in the reaction vessel during formation of the nanostructure.

In another aspect of the present invention, the nanostructure is a nanotube in which the [symbol] core has been filled with another material such as a metal to form a metallic [symbol] .

In a further embodiment of the present invention, chemical modification of the nanostructure may be performed in order to enhance or tailor the properties of the nanostructure. Thus, in the case of lithium nitride it is possible to oxidise partially the nanostructure either to produce a non-stoichiometric structure containing lithium, nitrogen and oxygen or to produce a nanostructure effectively based on lithium oxide.

In another aspect of the present invention, there is provided a process for the production of a nanostructure as defined previously, the process comprising exposing the metal of Group IA or IIA to a gaseous source of the element of Group IIIA, IVA, or VA, optionally in the presence of a transition metal, in a sealed heated chamber at a pressure between atmospheric pressure and a pressure of 10⁻⁴ torr, wherein the upper limit of the temperature is not more than 1200° C.

Preferably, in the process the upper limit of the temperature is defined by the temperature of decompostion of the compound.

In an embodiment, the process is used to make lithium nitride. In this case, lithium is heated in the presence of nitrogen in a sealed vessel until the pressure in the vessel is constant to form a lithium nitride nanostructure.

Inorganic nanostructures, such as those based on lithium nitride are expected to be of benefit in a number of applications on account of the number of different properties which are available from materials of this type. Thus, for example lithium nitride is a superionic conductor and nanostructures derived from lithium nitride therefore are likely to find application in materials such as rechargeable nano-batteries and other electronic components. This is one application for which carbon nanostructures are clearly unsuitable.

The anisotropic structures of the present invention, including but not limited to rods, fibres, tubes, have a number of applications on account of their properties.

Thus the nanostructures of the present invention have a number of applications such as: ionic conductors/battery components, in hydrogen storage devices, for templating nanowires, electrical devices, catalysis and synthesis, flat screen technology (display screens), and in mechanical applications as structural members. Inorganic nanostructures according to the present invention are capable of fulfilling all of these applications.

In the case of ionic conductors/battery components, modification of the lithium nitride nanostructure by the partial substitution of the group IA or IIA metal for another element such as cobalt, nickel, copper, iron, manganese or zinc etc lead to modulation of the electronic properties such as improved conductivity due to increased vacancy levels and reduced activation energies. There are also improvements in stability of the structures. Accordingly, these materials will be ideally suitable for use as components in small rechargeable batteries. Thus, in one embodiment of this aspect of the invention unmodified lithium nitride forms the electrolyte and substituted lithium nitride nanostructures form the electrodes. Presently, there is no nanotube system which is capable of being an ionic conductor and thus capable of incorporation into a battery.

The inorganic nanotubes of the present invention are expected to show enhanced hydrogen storage capacity compared with carbon nanotube systems. Thus, in a further aspect of the present invention relates to the use of a nanotube structure based on an inorganic material, such as lithium nitride, to accommodate and store hydrogen within the structure. Such a structure containing hydrogen will also benefit from an improved ionic conductivity. This method of inclusion of hydrogen within the structure provides an alternative method of storing hydrogen rather than just in the form of absorbed molecules and is expected to find use in application where the ability to store a large volume of hydrogen is important. Examples of such use include advanced fuel cells for vehicles.

Although it has been shown to be possible to fill carbon nanotubes with metal in order to form metallic nanowire through the centre of the tube there is the problem that subsequent removal of the carbon nanotube template to release the nanowire requires harsh conditions. In contrast, the inorganic nanotubes of the present invention are easy to remove after filling with metal to form a nanowire as they may be decomposed under appropriate (mild) conditions in the presence of water or air. This represents a significant advantage relative to the more forcing conditions required in the case of carbon nanotubes. Thus another aspect of the invention relates to a nanowire derived from an inorganic nanotube.

The inorganic nanostructures of the present invention can also be used to form electronic devices. Conventional carbon nanotubes have been proposed as nanoscale components such as transistors. However, ionic conductors based on the inorganic nanostructures of the present invention offer an alternative for these systems. Thus, in the case of lithium nitride, the superionic conductivity and availability of a number of different valency bands allows a range of conductivity properties to be exploited and thus a number of devices to be produced.

The nanostructures of the present invention also provide materials which can be used as catalysts in reactions. The nanostructure morphology such as catalysts formed into nanotubes or nanophilaments offer advantages over the use of powders in terms of the size, surface area and shapes selectivity of the active catalytic surface. The nanostructures of the present invention may be used either in their free form or when immobilised to a suitable substrate. In addition, the possibility of chirality in the nanostructure means that the catalysts may be used as chiral catalysts.

The electronic properties of inorganic nanostructures such as lithium nitride nanotubes also lead to an application in flat screen technology as emitting diodes (field emitting displays).

Certain of the inorganic nanostructures of the present invention display also extremely high tensile strengths along their length. Also, advantageous compressive properties and/or flexural properties (such as shear deformation) are seen in these materials. Thus, for example, lithium nitride nanotubes may be used as structural elements in certain devices.

Synthesis of the nanoscale structures can be achieved either directly or indirectly. The exact mechanism of the formation of the nanostructures of the present invention is not clear. However, a number of features are believed to be important in ensuring the formation of a nanostructure.

The shape and size of the reaction vessel is important. We have found that a long narrow shape is important in establishing a temperature gradient. Ideally the length of the vessel should be at least twice its diameter in order to ensure a favourable temperature gradient. Temperature gradients are particularly important in chemical vapour transport techniques for producing inorganic nanostructures such as those of the chalcogenides.

We have also found that the product only forms if the pressure is reduced below atmospheric pressure. However, we have also found that it is still necessary for there to be a certain amount of gas present in the reactor vessel and it is believed that this behaves as a transport gas. There is, however, a lower limit to the pressure in the reaction vessel and we have found that the synthesis does not progress well below a pressure of 10⁻⁴ torr. The upper limit of the acceptable pressure range is atmospheric pressure.

It is also important that the temperature is sufficiently high that the inorganic compound becomes volatile. In the case of lithium nitride a suitable temperature range is between 150° C. and 300° C. depending on the pressure in the reaction vessel. The upper limit of the temperature is governed by the need to avoid decomposition of the inorganic compound, although some decomposition may be tolerated as it is believed that the individual elements may be transported and recombined in the vapour phase in certain inorganic compounds.

The presence of a transition metal in the reaction vessel during the formation of certain inorganic compounds has been found to be beneficial in producing the nanostructure or to alter the nature of the nanostructure. Thus, in the case of lithium nitride, the presence of iron powder in the reaction vessel leads to an alteration in the manner in which the sheets roll up. Thus, the presence of a transition metal may have a catalytic and/or structure directing effect in the formation of an inorganic nanostructure. In addition, there is the possibility of integrating (substituting) the transition metal into the walls of the inorganic nanostructure.

The present invention will now be illustrated with reference to the example of the preparation of an inorganic nanostructure based on lithium nitride. Lithium nitride can be formed by exposing lithium metal to nitrogen gas at room temperature. Alternatively, lithium can be heated in the presence of nitrogen. Lithium nitride can also be produced by using molten sodium as a solvent for lithium which is then reacted with nitrogen.

The dissolution of lithium in sodium is carried out in an argon-filled glove box and the sodium is kept molten using a hot plate to provide heating. The molten sodium keeps the argon atmosphere clean by reacting with any residual oxygen gas or water vapour which may be present. The lithium is dissolved in the molten sodium and the crucible containing the mixture is then removed from the hot plate and allowed to cool. Once cool, the crucible is sealed in a reaction vessel in a furnace again in an argon gas atmosphere and heat and nitrogen are supplied. A clump of red fibrous material, consisting of lithium nitride nanotubes, grows above the crucible on a convenient surface provided within the furnace. Suitable surfaces include, for example, a loop of iron wire. The argon gas atmosphere is removed using a suitable pump and is replaced with nitrogen which is introduced under a positive pressure (typically 1.5 atmospheres). The reactants are heated to between 400 and 500° C., preferably about 460° C., for up to 72 hours and the pressure in the reaction vessel is monitored with a pressure transducer to measure pressure changes during the reaction. After a suitable period of time, usually between 6 and 72 hours, the reaction is complete and the point of completion can be measured by the pressure transducer. The pressure in the reaction vessel is constant once the reaction is complete and the vessel is then quenched to room temperature.

The reaction vessel includes a cold finger into which water is then placed and the vessel evacuated to a pressure of 10⁻⁴ torr or less. The vessel is again heated to between 400 and 500° C., preferably about 450° C., for up to 24 hours under a dynamic vacuum in order to distill off the sodium which recondenses on the cold finger. Lithium nitride in the form of a purple crystalline product remains in the crucible and may be collected.

1. An anisotropic nanoscale structure formed from at least one element selected from groups IA and IIA of the periodic table and at least one element selected from groups IIIA, IVA, and VA wherein the structure is a nanotube, nanorod or nanofibre.

2. A nanoscale structure as claimed in claim 1, wherein, the nanostructure is inorganic.

3. A nanoscale structure as claimed in claim 1, wherein the element of group IA is lithium, sodium or potassium.

4. A nanoscale structure as claimed in claim 3, wherein the element of group IA is lithium.

5. (canceled)

6. A nanoscale structure as claimed in claim 1, wherein, the structure is a nanotube.

7. A nanoscale structure as claimed in claim 1, wherein the non-metallic element selected from groups IIIA, IVA, and VA is one or more of boron, carbon, silicon or nitrogen.

8. A nanoscale structure as claimed in claim 7, wherein the non-metallic element is nitrogen.

9. A nanoscale structure as claimed in claim 1 in which some of the metallic element of group IA and IIA has been replaced with another element selected from hydrogen and/or a transition metal.

10. A nanoscale structure as claimed in claim 2, wherein the nanostructure is a nanotube in which the hollow core has been filled with a metal to form a metallic nanowire.

11. A nanoscale structure as claimed in claim 2, wherein chemical modification of the nanostructure has been performed in order to enhance or tailor the properties of the nanostructure.

12. An anisotropic nanoscale structure based on lithium nitride (Li₃N).

13. Use of an anisotropic nanostructure according to claim 2 in an ionic conductor/battery component, a hydrogen storage device, for templating nanowires, an electrical device, catalysis, a flat display screen, or as a structural member.

14. A process for the production of a nanostructure as defined in claim 1, the process comprising exposing the metal of Group IA or IIA to a gaseous source of the element of Group IIIA, IVA, or VA, in a sealed heated chamber at a pressure between atmospheric pressure and a pressure of 10⁻² Pa (10⁻⁴ torr), wherein the upper limit of the temperature is not more than 1200° C., and wherein said chamber comprises a cold finger into which water is placed.

15. A process as claimed in claim 14, wherein the upper limit of the temperature is defined by the temperature of decompostion of the compound.

16. A process as claimed in claim 14, wherein lithium is heated in the presence of nitrogen in a sealed vessel until the pressure in the vessel is constant to form a lithium nitride nanostructure.

17. A process as claimed in claim 14 wherein exposing the metal of Group IA or IIA to a gaseous source of the element of Group IIIA, IVA, or VA is further in the presence of a transition metal.

18. A process as claimed in claim 15, wherein lithium is heated in the presence of nitrogen in a sealed vessel until the pressure in the vessel is constant to form a lithium nitride nanostructure.
